(19) United States
(12) Patent Application Publication
(10) Pub. No.: US 2006/0286465 A1
(43) Pub. Date: Dec. 21, 2006

(54) Film type filter and display apparatus comprising the same

(76) Inventor: Ji-Suk Kim, Suwon-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/444,252

(22) Filed: May 30, 2006

(30) Foreign Application Priority Data
Jun. 15, 2005 (KR) 10-2005-0051360
Aug. 1, 2005 (KR) 10-2005-0070261
Aug. 1, 2005 (KR) 10-2005-0070262

(51) Int. Cl. G03F 1/00

(52) U.S. Cl. 430/7

(57) ABSTRACT

Provided are a film type filter which is light and can reduce the problem of double image reflection in a plasma display apparatus, and a plasma display apparatus having the film type filter. The film type filter includes a non-glass base film and an antiglare layer located over the non-glass base film.

### CROSS-REFERENCE TO RELATED APPLICATIONS

This application claims the benefit of Korean Patent Application No. 10-2005-0051360 filed on Jun. 15, 2005, Korean Patent Application No. 10-2005-0070261 filed on Aug. 1, 2005 and Korean Patent Application No. 10-2005-0070262 filed on Aug. 1, 2005, in the Korean Intellectual Property Office, the disclosures of which are each incorporated herein in their entirety by reference.

### BACKGROUND OF THE INVENTION

1. Field of the Invention

The present embodiments relate to a film type filter and a plasma display apparatus having the same.

2. Description of the Related Art

A plasma display apparatus is a flat display device that uses a plasma display panel and a plasma discharge to display an image. Due to its high display performances such as high brightness, high contrast, clear latent image, large viewing angle, and large thin screen, the plasma display apparatus is considered to be one of the next generation display devices.

However, in a conventional plasma display apparatus, there is a problem of double image reflection due to different refraction indexes of a front substrate and a reinforcing glass filter of the plasma display panel. Also, the reinforcing glass filter is heavy, since it must have a predetermined thickness (approximately 3 mm) to resist to an external impact, and expensive. Also, the conventional reinforcing glass filter has a very complicated structure composed of films having various functions. Thus, the films are complicated and expensive, thereby increasing the manufacturing cost of the plasma display apparatus.

### SUMMARY OF THE INVENTION

The present embodiments provide a film type filter which is light and can reduce the problem of double image reflection in a plasma display apparatus, and a plasma display apparatus having the film type filter.

The present embodiments also provide a film type filter that can be easily manufactured at lower costs, and a plasma display apparatus having the film type filter.

The present embodiments also provide a film type filter that reduces glare, thereby improving the viewing comfort of a user, and a plasma display apparatus having the film type filter.

According to an aspect of the present embodiments, there is provided a film type filter comprising a non-glass base film and an antiglare layer located over the non-glass base film.

According to another aspect of the present embodiments, there is provided a plasma display apparatus comprising: a plasma display panel for displaying an image; and a film type filter which is attached onto the front surface of the plasma display panel, which comprises a non-glass base film and an antiglare layer located over the non-glass base film.

According to another aspect of the present embodiments, there is provided a display apparatus further comprising an electromagnetic wave shielding layer located on the non-glass base film.

According to another aspect of the present embodiments, there is provided a display apparatus wherein the electromagnetic wave shielding layer comprises at least one metal layer or metal oxide layer.

According to another aspect of the present embodiments, there is provided a display apparatus wherein the electromagnetic wave shielding layer comprises at least one metal selected from the group consisting of Ag, ITO, Cu, Au, and Al.

According to another aspect of the present embodiments, there is provided a display apparatus wherein the electromagnetic wave shielding layer has a mesh shape.

According to another aspect of the present embodiments, there is provided a display apparatus further comprising an adhesive layer on the non-glass base film.

According to another aspect of the present embodiments, there is provided a display apparatus wherein the adhesive layer comprises a dye or a pigment to correct color.

According to another aspect of the present embodiments, there is provided a display apparatus wherein there is no substantial air gap between the film type filter and the display panel.

According to another aspect of the present embodiments, there is provided a display apparatus wherein the display apparatus is one selected from the group consisting of a plasma display, an organic light emitting display and a liquid crystal display.

### BRIEF DESCRIPTION OF THE DRAWINGS

The above and other features and advantages of the present embodiments will become more apparent by describing in detail exemplary embodiments thereof with reference to the attached drawings in which:

FIG. 1 is a perspective view of a film type filter according to an embodiment;

FIG. 2 is a cross-sectional view taken along line II-II of FIG. 1;

FIG. 3 is a cross-sectional view of a modified version of the film type filter of FIG. 1;

FIG. 4 is a cut-away perspective view of a film type filter according to another embodiment;

FIG. 5 is a cross-sectional view of a film type filter according to still another embodiment;

FIG. 6 is an exploded perspective view of a plasma display apparatus according to an embodiment; and

FIG. 7 is a cross-sectional view taken along line V-V of FIG. 6.

### DETAILED DESCRIPTION OF THE INVENTION

The present embodiments will now be described more fully with reference to the accompanying drawings in which exemplary embodiments are shown.

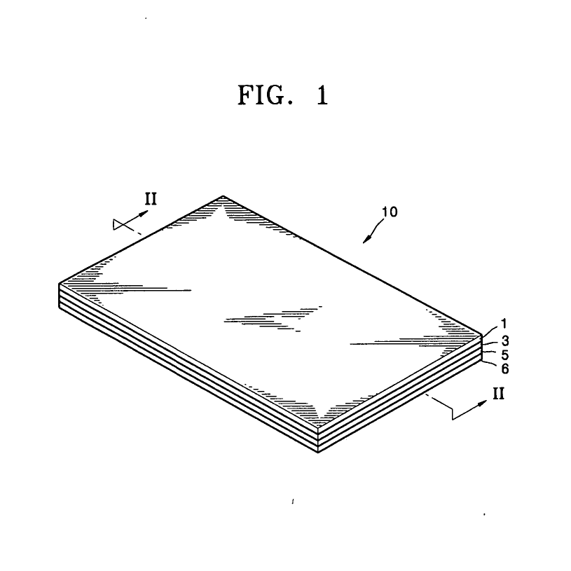

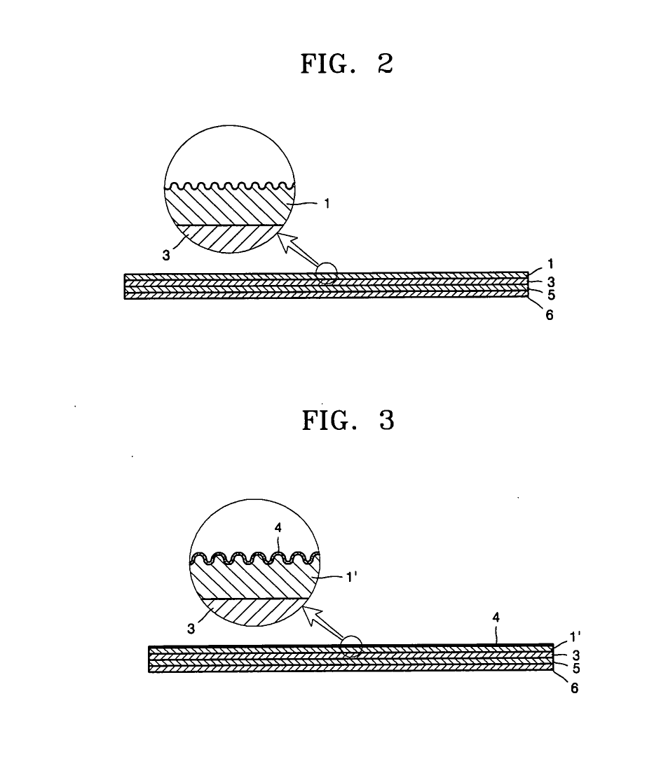

FIG. 1 is a perspective view of a film type filter according to an embodiment, and FIG. 2 is a cross-sectional view taken along line II-II of FIG. 1. A film type filter 10 according to an embodiment will now be described with reference to FIGS. 1 and 2.

Referring to FIGS. 1 and 2, the film type filter 10 includes a non-glass base film 3, an antiglare layer 1, an electromagnetic wave shielding layer 5, and an adhesive layer 6.

The non-glass base film 3 may be generally formed of a material having high visible light transmittance, but it can be colored for increasing bright room contrast. The non-glass base film 3 can be formed of polyethersulphone (PES), polyacrylate (PAR), polyetherimide (PEI), Polyethylene naphthalate (PEN), polyethylene terephthalate (PET), polyphenylene sulfide (PPS), polyallylate, polyimide, polycarbonate (PC), cellulose triacetate (cellulose TAC), or cellulose acetate propionate (CAP), and more preferably, PC, PET, cellulose TAC, or PEN.

Also, the non-glass base film 3 has a flat shape and has preferably a thickness of from about 50 to about 500 μm. The non-glass base film 3 has more preferably a thickness of from about 80 to about 400 μm.

The antiglare layer 1 is located over the non-glass base film 3. The antiglare layer 1 disperses external light incident on a surface thereof, and prevents other external light from reaching the surface of the film type filter 10. If the antiglare layer 1 is applied to a conventional reinforcing glass filter, there is a disadvantage of reducing image definition due to a gap between the front substrate and the reinforcing glass filter. Therefore, the antiglare layer 1 cannot be applied to the conventional reinforcing glass filter. However, in the present embodiments, since the film type filter 10 is directly attached onto the display panel, the definition reduction problem does not occur. Therefore, the antiglare layer 1 can be applied to the film type filter 10 according to the present embodiments.

The antiglare layer 1 can be formed by finely corrugating the top surface of the non-glass base film 3. Recently, there is a high demand for plasma display panels with wide viewing angle, quick response time, and high image quality (high image resolution). High resolution is obtained by reducing pixel size. However, as the pixel size is reduced, that is, if the resolution is greater than about 133 ppi (pixels/inch), light that reaches the viewer's eyes generates a luminance deviation, thereby causing a glare on the viewer's eyes. The luminance deviation is caused by the collection of light emitted from a single pixel due to a lensing effect or by mixing of red, green, and blue lights emitted from sub-pixels, since the surface of the non-glass base film 3 has a larger roughness than the size of the pixels that display an image. Therefore, the height of the finely corrugated surface of the antiglare layer 1 should be smaller than the size of the pixels.

The antiglare layer 1 can be formed, for example, by a dipping coating method, an air-knife method, a curtain coating method, a roller coating method, a wire-bar coating method, or a gravure coating method.

The antiglare layer 1 may include a hard coating material. The plasma display apparatus having the film type filter 10 may be subjected to various kinds of external forces while operating. Therefore, there is a high risk of scratching the display apparatus. Accordingly, the hard coating material can prevent scratching. However, in the present embodiment, the hard coating material is included in the antiglare layer 1, but as depicted in FIG. 3, an additional hard coating material layer 4 can be formed on the antiglare layer 1′.

The hard coating material may include a polymer as a binder, such as an acryl group polymer, a urethane group polymer, an epoxy group polymer, or a siloxane group polymer, or an ultraviolet ray hardening resin such as an oligomer. A silica group filler can further be included in the hard coating material to increase hardness.

Also, the antiglare layer 1 may have a thickness of from about 2 to about 7 μm and a pencil hardness of from about 2 to about 3 H, but the present embodiments are not limited thereto.

The electromagnetic wave shielding layer 5 is located on the other surface of the non-glass base film 3. The electromagnetic wave shielding layer 5 shields electromagnetic waves generated from the display apparatus, which are harmful to the human body. The electromagnetic wave shielding layer 5 is formed by stacking at least one layer of a metal layer or a metal oxide layer, and preferably, has a multilayer structure in which 5 to 11 layers are stacked. Particularly, when the metal oxide layer and the metal layer are stacked together, the metal oxide layer can prevent oxidation or degradation of the metal layer. Also, when the electromagnetic wave shielding layer 5 is formed as a multiple layer by stacking layers, not only the surface resistance of the electromagnetic wave shielding layer 5 can be corrected, but also the transmittance of visible light can be controlled.

The metal layer can be formed of, for example, palladium, copper, platinum, rhodium, aluminum, iron, cobalt, nickel, zinc, ruthenium, tungsten, tin, iridium, lead, silver, or a composite of these metals.

Also, the metal oxide layer can be formed of, for example, tin oxide, indium oxide, antimony oxide, zinc oxide, zirconium oxide, titan oxide, magnesium oxide, silicon oxide, aluminum oxide, alcoxide, indium tin oxide, or antimony tin oxide (ATO).

The electromagnetic wave shielding layer 5 can be formed by sputtering, vacuum evaporation, ion plating, CVD, or PVD. However, in the present embodiments, the electromagnetic wave shielding layer 5 may be deposited in a structure in which ITO and Ag are individually or alternately stacked in 5 to 11 layers.

The metal layer or the metal oxide layer shields not only electromagnetic waves but also near infrared rays. Accordingly, the malfunctions of peripheral electronic devices due to the near infrared rays can be reduced.

The adhesive layer 6 is formed on the electromagnetic wave shielding layer 5. The adhesive layer 6 is used for attaching the film type filter 10 to the display panel. The adhesive layer 6 may be formed of a material having a predetermined diffraction index difference from the diffraction index of the display panel, for example, the diffraction index difference should not exceed 1% to reduce the double image reflection phenomenon.

The adhesive layer 6 may include a thermoplastic resin or a UV setting resin, for example, an acrylate group resin or a pressure sensitive adhesive (PSA). The adhesive layer 6 can be formed by a dipping coating method, an air-knife method, a curtain coating method, a roller coating method, a wire-bar coating method, or a gravure coating method.

The adhesive layer 6 can further include a compound that absorbs near infrared rays. The compound can be a resin that includes copper atoms, a resin that includes a copper compound or a phosphate compound, a resin that includes a copper compound or a thio-urea derivative, a resin that includes a tungsten compound, or a cyanine group compound.

Also, the adhesive layer 6 can further include a color material such as a pigment or a dye to correct color or to shield neon light. The color material selectively absorbs light having a wavelength of about 400 to about 700 nm, which corresponds to visible light. Particularly, when a discharge is generated in the plasma display panel, unnecessary visible light having a wavelength of approximately 585 nm is generated by neon gas, which is a discharge gas. To absorb the visible light, compounds such as a cyanine group, a squarylium group, an azomethine group, a xanthene group, an oxonol group, or an azo group can be used. The adhesive layer 6 includes fine particles of pigment in a dispersed state.

When the film type filter 10 has the above structure, the light transmittance can be from about 30 to about 90%, and preferably, from about 40 to about 80%. Also, the film type filter 10 can have a haze of from about 3 to about 11%.

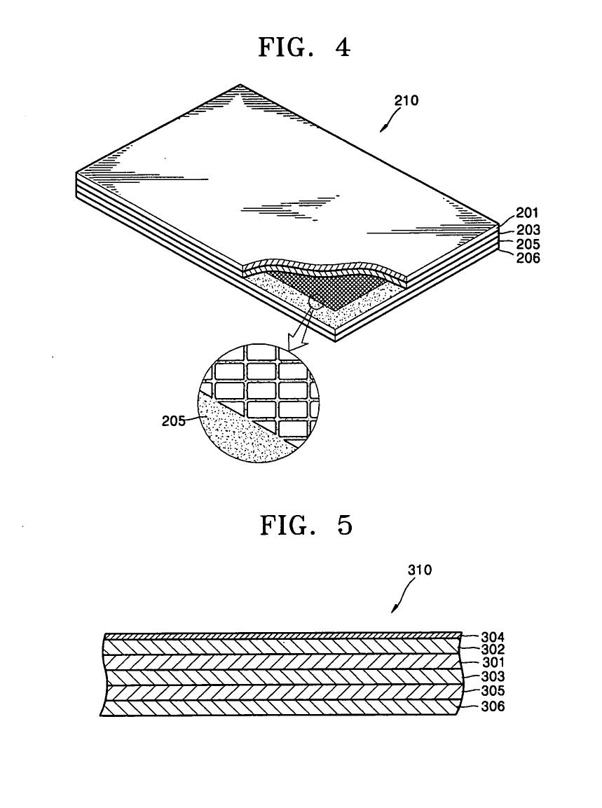

A film type filter 210 according to another embodiment will now be described with reference to FIG. 4. FIG. 4 is a cut-away perspective view of the film type filter 210 according to another embodiment.

Referring to FIG. 4, the film type filter 210 includes a non-glass base film 203, an antiglare layer 201, an electromagnetic wave shielding layer 205, and an adhesive layer 206.

The non-glass base film 203 is generally formed of a material having high visible light transmittance, but it can be colored to increase bright room contrast.

The antiglare layer 201 is located over the non-glass base film 203. The antiglare layer 201 scatters external light incident on a surface thereof, and prevents the irradiation of surrounding light around the film type filter 210 onto the surface of the film type filter 210.

The antiglare layer 201 may include a hard coating material. However, an additional hard coating material (not shown) can be formed on the antiglare layer 201.

The electromagnetic wave shielding layer 205 is located on the other surface of the non-glass base film 203. The electromagnetic wave shielding layer 205 shields harmful electromagnetic waves generated from the display apparatus. The electromagnetic wave shielding layer 205 may be formed in various shapes, but preferably may have a mesh shape to increase a shielding rate. In the case of the mesh shape, the electromagnetic wave shielding layer 205 has an oblique mesh shape as depicted in FIG. 4, but the present embodiments are not limited thereto. That is, the electromagnetic wave shielding layer 205 may have substantially a rectangular mesh shape, but it can have various shapes such as a circular mesh shape or an irregular mesh shape. Also, the electromagnetic wave shielding layer 205 can be formed of various metals, such as copper which has good workability and high electric conductivity.

The adhesive layer 206 is formed on the electromagnetic wave shielding layer 205. The adhesive layer 206 is used for attaching the film type filter 210 to the display panel. The adhesive layer 206 can further include a compound that absorbs near infrared rays. Also, the adhesive layer 206 can further include a color material such as a pigment or a dye for correcting color or shielding neon light.

In the case of a film type filter 210 having the above mentioned structure, the light transmittance can be from about 30 to about 90%, preferably, from about 40 to about 80%. Also, the film type filter 210 can have a haze of from about 3 to about 11%.

A film type filter 310 according to still another embodiment will now be described with reference to FIG. 5. FIG. 5 is a cross-sectional view of the film type filter 310 according to still another embodiment.

Referring to FIG. 5, the film type filter 310 includes a non-glass base film 303, an antiglare layer 301, an anti reflection layer 302, an electromagnetic wave shielding layer 305, and an adhesive layer 306.

The non-glass base film 303 is generally formed of a material having high visible light transmittance, but it can be colored to increase bright room contrast.

The antiglare layer 301 is located over the non-glass base film 303. The antiglare layer 301 scatters external light incident on a surface thereof, and prevents irradiation of surrounding light around the film type filter 310 onto the surface of the film type filter 310.

The anti reflection layer 302 is located on the antiglare layer 301. The anti reflection layer 302 reduces the reflectance of visible light incident from the outside and minimizes eye fatigue by controlling the visible light transmittance. Here, the control of the visible light transmittance includes the selective absorption of visible light to increase not only contrast but also a color reproducibility range.

The anti reflection layer 302 is formed in a multilayer film in which more than one metal oxide layers are stacked. The visible light transmittance can be controlled using the multilayer film. The metal oxide layer can be a mixture (composite) of indium tin oxide (ITO) and silicon oxide (SiO₂), or a mixture of NiCr and SiO₂.

The anti reflection layer 302 can be formed by a CVD method, a PVD method, or a vacuum evaporation method or PVD or sputtering.

The anti reflection layer 302 can include a hard coating layer 304 to prevent the display panel from being scratched.

The electromagnetic wave shielding layer 305 is located on the other surface of the non-glass base film 303. The electromagnetic wave shielding layer 305 shields electromagnetic waves generated from the display apparatus which are harmful to the human body. The electromagnetic wave shielding layer 305 is formed by stacking more than one layers of a metal or a metal oxide, and preferably, has a multilayer structure in which 5 to 11 layers are stacked.

The adhesive layer 306 is formed on the electromagnetic wave shielding layer 305. The adhesive layer 306 is used for attaching the film type filter 310 to the display panel. The adhesive layer 306 can further include a compound that absorbs near infrared rays. Also, the adhesive layer 306 can further include a color material such as a pigment or a dye to correct color or to shield neon light.

In the case of a film type filter 310 having the above mentioned structure, the light transmittance can be from about 30 to about 90%, preferably, from about 40 to about 80%. Also, the film type filter 310 can have a haze of from about 3 to about 11%.

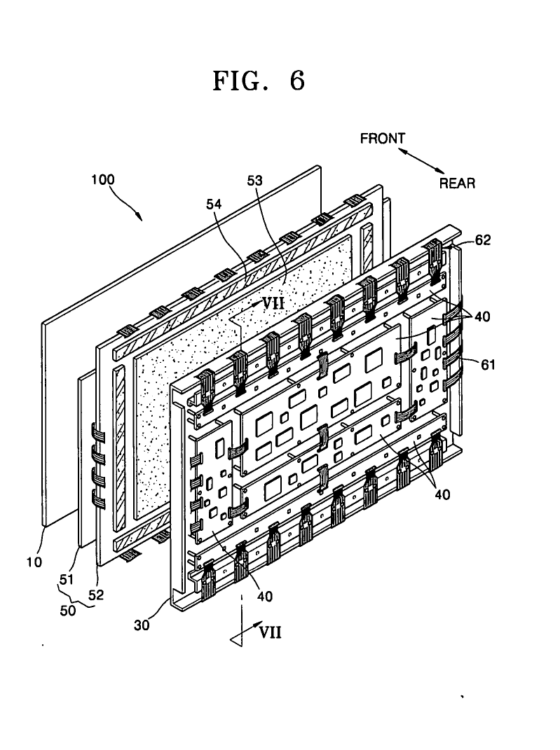

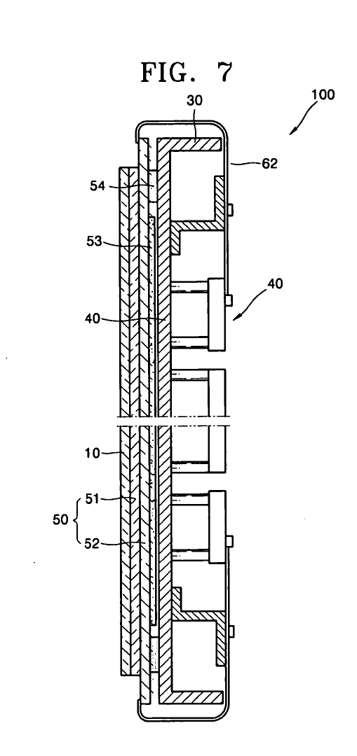

In FIGS. 6 and 7, a plasma display apparatus 100 having a film type filter 10 according to an embodiment is shown. FIG. 6 is an exploded perspective view of a plasma display apparatus 100 having the film type filter 10 according to an embodiment, and FIG. 7 is a cross-sectional view taken along line VII-VII of FIG. 6. In describing the plasma display panel 100, like elements that have been described in the aforementioned embodiments use like reference numerals. The plasma display apparatus 100 can include not only the film type filters according to the embodiments illustrated in FIGS. 4 and 5, but also film type filters having various shapes.

The plasma display apparatus 100 includes a film type filter 10, a plasma display panel 50, a chassis 30, a thermal conductive member 53, and a circuit unit 40.

The plasma display panel 50 displays an image, and includes a front panel 51 and a rear panel 52 coupled to each other.

The film type filter 10 is attached onto the front surface of the plasma display panel 50 by the adhesive layer 6. The film type filter 10 shields electromagnetic waves generated by the plasma display panel 50, reduces a glare phenomenon, and also, can shield infrared rays or neon light. Furthermore, the double image reflection problem can be fundamentally solved since the film type filter 10 is directly attached onto the front surface of the plasma display panel 50.

The chassis 30 is located on the rear of the plasma display panel 50 to structurally support the plasma display panel 50. The chassis 30 may be formed of a metal having high strength, such as aluminum or iron, or a plastic.

The thermal conductive member 53 is located between the plasma display panel 50 and the chassis 30. Also, a plurality of dual-sided tapes 54 are located along edges of the thermal conductive member 53, and the double-sided tapes 54 fix the plasma display panel 50 and the chassis 30 to each other.

The circuit unit 40 is located at the rear of the chassis 30 and includes a circuit for driving the plasma display panel 50. The circuit unit 40 transmits electrical signals to the plasma display panel 50 by a signal transmitting means. The signal transmitting means can be flexible printed cables (FPCs), tape carrier packages (TCP), or chip on films (COF). According to the present embodiment, FPCs 61 are located in the left side and the right side of the chassis 30, and TCPs 62 are located in the upper side and the lower side of the chassis 30.

A film type filter according to the present embodiments and a plasma display apparatus having the film type filter have the following advantages.

First, the double image reflection problem can be reduced since the film type filter is directly attached onto the front surface of the plasma display panel.

Second, since the film type filter is formed using a relatively thin non-glass base film, weight thereof is reduced, thereby reducing manufacturing costs.

Third, manufacturing is easy since layers having various functions can be stacked over the non-glass base film.

Fourth, glare is reduced due to a diffused reflection effect of an antiglare layer, and visibility is improved by reducing specular reflection.

While the present embodiments have been particularly shown and described with reference to exemplary embodiments thereof, it will be understood by those of ordinary skill in the art that various changes in form and details may be made therein without departing from the spirit and scope of the present embodiments as defined by the following claims.

What is claimed is:

1. A film type filter for a display device comprising:
a non-glass base film; and
an antiglare layer located over the non-glass base film.

2. The film type filter of claim 1, wherein the filter does not comprise a layer of glass.

3. The film type filter of claim 1, wherein the antiglare layer comprises a hard coating material to protect the film type filter from scratching by an external impact.

4. The film type filter of claim 3, wherein the antiglare layer has a pencil hardness of from about 2 to about 3 H and a thickness of from about 2 μm to about 7 μm.

5. The film type filter of claim 1, further comprising a hard coating layer on the antiglare layer.

6. The film type filter of claim 1, further comprising an anti reflection layer on the antiglare layer.

7. The film type filter of claim 6, further comprising a hard coating layer on the anti reflection layer.

8. The film type filter of claim 1, further comprising an electromagnetic wave shielding layer located on the non-glass base film.

9. The film type filter of claim 8, wherein the electromagnetic wave shielding layer comprises at least one metal layer or metal oxide layer.

10. The film type filter of claim 8, wherein the electromagnetic wave shielding layer comprises at least one material selected from the group consisting of Ag, ITO, Cu, Au, and Al.

11. The film type filter of claim 8, wherein the electromagnetic wave shielding layer has a mesh shape.

12. The film type filter of claim 1, further comprising an adhesive layer on the side of the non-glass base film.

13. The film type filter of claim 12, wherein the adhesive layer comprises a dye or a pigment to correct color.

14. The film type filter of claim 1, wherein at least one of the film type filter and the non-glass base film is flexible.

15. A display apparatus comprising:
a display panel for displaying an image; and a film type filter attached to the front surface of the display panel which comprises a non-glass base film and an antiglare layer located over the non-glass base film.

16. The display apparatus of claim 15, wherein the antiglare layer comprises a hard coating material to protect the film type filter from scratching by an external impact.

17. The display apparatus of claim 16, wherein the antiglare layer has a pencil hardness of from about 2 H to about 3 H.

18. The display apparatus of claim 16, wherein the antiglare layer has a thickness of from about 2 μm to about 7 μm.

19. The display apparatus of claim 15, further comprising a hard coating layer on the antiglare layer.

20. The display apparatus of claim 15, further comprising an anti reflection layer on the antiglare layer.

21. The display apparatus of claim 19, further comprising a hard coating layer on the anti reflection layer.

22. The display apparatus of claim 15, further comprising an electromagnetic wave shielding layer located on the non-glass base film.

23. The display apparatus of claim 22, wherein the electromagnetic wave shielding layer comprises at least one metal layer or metal oxide layer.

24. The display apparatus of claim 22, wherein the electromagnetic wave shielding layer comprises at least one metal selected from the group consisting of Ag, ITO, Cu, Au, and Al.

25. The display apparatus of claim 24, wherein the electromagnetic wave shielding layer has a mesh shape.

26. The display apparatus of claim 15, further comprising an adhesive layer on the non-glass base film.

27. The display apparatus of claim 26, wherein the adhesive layer comprises a dye or a pigment to correct color.

28. The display apparatus of claim 15, wherein there is no substantial air gap between the film type filter and the display panel.

29. The display apparatus of claim 15, wherein the display apparatus is one selected from the group consisting of a plasma display, an organic light emitting display and a liquid crystal display.

30. The display apparatus of claim 15, wherein at least one of the film type filter and the non-glass base film is flexible.
